(19) United States
(12) Patent Application Publication
(10) Pub. No.: US 2026/0190814 A1
(43) Pub. Date: Jul. 2, 2026

(54) DISPLAY DEVICE

(71) Applicant: LG Display Co., Ltd., Seoul (KR)

(72) Inventors: Sangug An, Gumi-si (KR); Wooram Oh, Chilgok-gun (KR)

(73) Assignee: LG Display Co., Ltd., Seoul (KR)

(21) Appl. No.: 19/432,608

(22) Filed: Dec. 24, 2025

(30) Foreign Application Priority Data
Dec. 30, 2024 (KR) 10-2024-0201072

(51) Int. Cl. H10K 59/80; G06F 3/041; H10K 59/40

(52) U.S. Cl. CPC H10K 59/879; H10K 59/40; G06F 3/0412

(57) ABSTRACT

A display device includes a substrate including a plurality of sub-pixels, a light emitting element disposed in each of the plurality of sub-pixels, an encapsulation layer disposed on the light emitting element, and a touch unit disposed on the encapsulation layer. The touch unit includes a black matrix which is disposed on the encapsulation layer and has a plurality of openings which overlaps the plurality of sub-pixels, a plurality of sensor metals disposed on the black matrix, a plurality of lenses which is disposed on the plurality of sensor metals and overlaps the plurality of sub-pixels, and a plurality of sensor variable regions disposed between the plurality of sensor metals. The plurality of sensor variable regions are disposed in an area between the plurality of lenses.

### CROSS-REFERENCE TO RELATED APPLICATIONS

This application claims the priority of Korean Patent Application No. 10-2024-0201072, filed on Dec. 30, 2024, in the Korean Intellectual Property Office, the disclosure of which is incorporated herein by reference.

### FIELD

The present disclosure relates to a display device, and more particularly, to a display device in which a touch unit is embedded.

### BACKGROUND

An electroluminescent display device is a self-emitting display device and does not require a separate light source unlike a liquid crystal display device, and thus may be manufactured as a lightweight, thin display device. In addition, the electroluminescent display device is advantageous not only in terms of power consumption due to low voltage driving, but also in terms of color implementation, response speed, viewing angle, and contrast ratio (CR), so it is being studied as a next-generation display.

Among the electroluminescent display devices, there is a touch screen integrated display device including a touch unit capable of recognizing a user's touch. Since the touch screen integrated display device can directly input information using a finger or a pen, it is widely applied to navigation, portable terminals, and home appliances.

### SUMMARY

An object to be achieved by the present disclosure is to provide a display device in which a touch unit is embedded.

Another object to be achieved by the present disclosure is to provide a display device in which a touch unit including a variable region in which a metal is selectively disposed is embedded.

Still another object to be achieved by the present disclosure is to provide a display device in which a metal of a touch unit is not visible.

Still another object to be achieved by the present disclosure is to provide a display device in which a variable sensor area is formed to be spaced apart from an area included in a position deviation range of a lens, thereby minimizing or reducing visibility of a touch electrode.

Still another object to be achieved by the present disclosure is to provide a display device in which a metal is formed in a sensor variable region and a bridge variable region to form various connection structures between a sensor metal and a bridge metal.

Objects of the present disclosure are not limited to the above-mentioned objects, and other objects, which are not mentioned above, can be clearly understood by those skilled in the art from the following descriptions.

To achieve these objects and other advantages of the present disclosure, as embodied and broadly described herein, a display device according to an example embodiment of the present disclosure includes: a substrate including a plurality of sub-pixels; a light emitting element disposed in each of the plurality of sub-pixels; an encapsulation layer disposed on the light emitting element; and a touch unit disposed on the encapsulation layer, the touch unit including a black matrix having a plurality of openings which is disposed on the encapsulation layer and overlaps the plurality of sub-pixels; a plurality of sensor metals disposed on the black matrix; a plurality of lenses which is disposed on the plurality of sensor metals and overlaps the plurality of sub-pixels; and a plurality of sensor variable regions disposed between the plurality of sensor metals, wherein the plurality of sensor variable regions are disposed in an area between the plurality of lenses. Accordingly, the plurality of sensor variable regions are disposed so as not to overlap the lens so that the shape of the pattern of the plurality of sensor variable regions is not limited to the positional deviation of the lens and may be kept constant.

Other detailed matters of various example embodiments are included in the detailed description and the drawings.

According to one or more example embodiments the present disclosure, it is possible to provide a display device in which a touch unit is embedded.

According to one or more example embodiments the present disclosure, it is possible to provide a display device in which a touch unit including a variable region in which a metal is selectively disposed is embedded.

According to one or more example embodiments the present disclosure, it is possible to implement the metal of the touch unit so as not to be visually recognized.

According to one or more example embodiments the present disclosure, the sensor variable region is formed outside the expected placement area of the lens, so that the shape of the pattern of the sensor metal may be prevented or suppressed from changing according to the placement of the lens.

According to one or more example embodiments the present disclosure, various connection structures of the sensor metal may be formed by forming a metal in the sensor variable region.

According to one or more example embodiments the present disclosure, various connection structures of the bridge metal may be formed by forming a metal in the bridge variable region.

The effects according example embodiments to the present disclosure are not limited to the contents exemplified above, and various additional effects can be attained from the present disclosure.

### BRIEF DESCRIPTION OF DRAWINGS

The accompanying drawings, which are included to provide a further understanding of the present disclosure and are incorporated in and constitute a part of this application, illustrate embodiments of the present disclosure and together with the description serve to explain various principles of the disclosure. The above and other aspects, features, and advantages of the present disclosure can be more clearly understood from the following detailed description taken in conjunction with the accompanying drawings.

FIG. 1A is a schematic configuration diagram of a display device according to an example embodiment of the present disclosure.

FIG. 1B is a view illustrating an example of using a display device according to an example embodiment of the present disclosure.

FIG. 1C is an example plan view of a display device according to an example embodiment of the present disclosure.

FIGS. 2 and 3 are schematic plan views of a touch unit of a display device according to an example embodiment of the present disclosure.

FIG. 4 is an enlarged plan view of a display device according to an example embodiment of the present disclosure.

FIG. 5 is an example enlarged plan view of an area X of FIG. 4.

FIG. 6 is a cross-sectional view taken along line A-A′ in FIG. 5.

FIG. 7A is an example enlarged plan view of an area Y of FIG. 5.

FIG. 7B is a cross-sectional view taken along line B-B′ in FIG. 7A.

FIG. 8A is an example enlarged plan view of an area Y of FIG. 5.

FIG. 8B is a cross-sectional view taken along line C-C′ in FIG. 8A.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with a more specific term like “only.” Any references to singular may include plural, vice versa, unless expressly stated otherwise.

Components are to be interpreted to include an ordinary error range even if not expressly stated.

Where the position relation between two parts is described using such terms as “on,” “above,” “below,” and “next,” one or more parts may be positioned between the two parts unless the terms are used with a more specific term like “immediately” or “directly.”

Where an element or layer is described as being disposed “on” another element or layer, another layer or another element may be interposed directly on the other element or therebetween.

Although the terms “first,” “second,” and the like may be used for describing various components, these components are not confined by these terms. These terms are merely used for referring to one component separately from the other components. Therefore, a first component to be mentioned below may be a second component, and vice versa, in a technical concept of the present disclosure.

Like reference numerals generally denote like elements throughout the disclosure, unless otherwise specified.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, example embodiments of the present disclosure will be described in detail with reference to accompanying drawings.

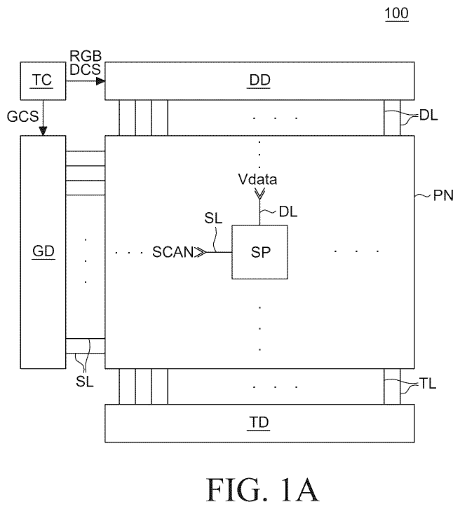

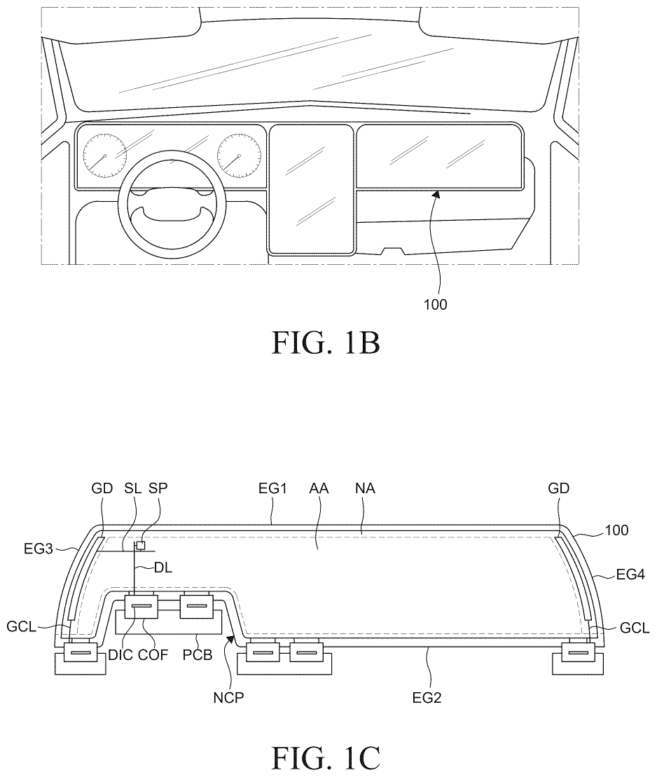

FIG. 1A is a schematic configuration diagram of a display device according to an example embodiment of the present disclosure. FIG. 1B is a view illustrating an example of using a display device according to an example embodiment of the present disclosure. FIG. 1C is an example plan view of a display device according to an example embodiment of the present disclosure. In FIG. 1A, for the convenience of description, among various components of the display device 100, only a display panel PN, a gate driver GD, a data driver DD, a touch driver TD, and a timing controller TC are illustrated.

As shown in FIG. 1A, a display device 100 includes a display panel PN including a plurality of sub-pixels SP, a gate driver GD and a data driver DD which supply various signals to the display panel PN, a timing controller TC which controls the gate driver GD and the data driver DD, and a touch driver TD which senses a touch input.

The display panel PN is configured to display images to a user and includes a plurality of sub-pixels SP. In the display panel PN, the plurality of scan lines SL and the plurality of data lines DL intersect each other, and each of the plurality of sub-pixels SP is connected to the scan line SL and the data line DL. In addition, although not illustrated in the drawings, each of the plurality of sub-pixels SP may be connected to a high potential power line, a low potential power line, a reference line, and the like.

The plurality of sub-pixels SP is a minimum unit constituting a screen, and each of the plurality of sub-pixels SP includes a light emitting element and a pixel circuit for driving the light emitting element. The plurality of light emitting elements may be differently defined depending on the type of the display device 100. For example, when the display device 100 is an organic light emitting display device 100, the light emitting element may be an organic light emitting element (OLED).

The gate driver GD supplies a plurality of scan signals SCAN to a plurality of scan lines SL according to a plurality of gate control signals GCS provided from the timing controller TC. FIG. 1 illustrates that one gate driver GD is disposed to be spaced apart from one side of the display panel PN. However, the number and arrangement of the gate drivers GD are not limited thereto.

The data driver DD converts image data RGB transmitted from the timing controller TC into a data voltage Vdata using a reference gamma voltage according to a plurality of data control signals DCS provided from the timing controller TC. The data driver DD may supply the converted data voltage Vdata to the plurality of data lines DL.

The timing controller TC aligns image data RGB input from the outside and supplies the image data RGB to the data driver DD. The timing controller TC may generate a gate control signal GCS and a data control signal DCS by using a synchronization signal input from the outside, for example, a dot clock signal, a data enable signal, and a horizontal/vertical synchronization signal. Further, the timing controller TC supplies the generated gate control signal GCS and data control signal DCS to the gate driver GD and the data driver DD, respectively, to control the gate driver GD and the data driver DD.

The touch driver TD drives the touch unit 150 during a touch sensing period based on a touch enable signal input from the timing controller TC or an external component. The touch driver TD may sense a touch input based on a signal from the touch unit 150.

As shown in FIGS. 1B and 1C together, the display device 100 is not limited to a TV, a monitor, or a mobile phone and may be used in various fields. For example, the display device 100 may be used for a dashboard of a vehicle. The display device 100 of the dashboard may be disposed in front of the vehicle. For example, the display device 100 of the dashboard may be disposed in at least one of the driver's seat and the front passenger seat, or may be disposed to extend from the driver's seat to the front passenger seat.

The display device 100 of the vehicle may serve as an input unit for displaying various information related to the vehicle or manipulating various functions of the vehicle. Specifically, the display device 100 may display an interface for operating an air conditioner, an audio system, a navigation system, or the like of a vehicle, or display information such as a speed, a fuel amount, and a driving distance of the vehicle.

As shown in FIG. 1C, the display device 100 may have a general rectangular shape, but may have various shapes depending on a product to which the display device 100 is to be applied. For example, when the display device 100 is applied to the vehicle, the display device 100 may have a heterogeneous shape including curved surfaces and a notch portion NCP as illustrated in FIG. 1C.

Specifically, the display device 100 may include an upper first edge EG1 extending in a straight line, a lower second edge EG2 having a notch portion NCP, a left third edge EG3 formed of a curved surface, and a right fourth edge EG4 formed of a curved surface.

In the notch portion NCP, a portion of the display device 100 may be notched and formed to be concave.

The display area AA may also include edges corresponding to the edges EG1, EG2, EG3 and EG4 of the display device 100. The display area AA may include a concave portion corresponding to the notch portion NCP, a convex side portion corresponding to the curved third edge EG3 and the fourth edge EG4, and the like.

The plurality of flexible films COF each including the driving IC DIC may be connected to the second edge EG2 of the display device 100. The flexible film COF may be a film in which various components are disposed on a base film having flexibility. For example, a driving IC DIC, which is a component that includes a data driver DD and processes data for displaying images and a driving signal, may be disposed on the flexible film COF. Some of the plurality of flexible films COF may be connected to a part of the second edge EG2 corresponding to the notch portion NCP, and the rest may be connected to the rest of the second edge EG2 excluding the notch portion NCP.

The printed circuit board PCB may be electrically connected to one or more flexible films COF and supply signals to the driving IC DIC. The printed circuit board PCB may be electrically connected to the flexible film COF. Various components for supplying various signals to the driving IC DIC may be disposed on the printed circuit board PCB. For example, various components such as a timing controller TC, a power management integrated circuit (PMIC), a memory, or a processor may be disposed on the printed circuit board (PCB).

The gate driver GD is disposed in the non-display area NA on both sides of the display area AA, that is, the non-display area NA on the third edge EG3 and the fourth edge EG4. The gate driver GD may be driven by receiving a signal from the flexible film COF through the gate driving line GCL. The gate driver GD may be disposed along the curved third edge EG3 and the fourth edge EG4 and may be disposed in a heterogeneous region.

The low potential power line VSSL is disposed in the non-display area NA. The low potential power line VSSL may receive a signal from the flexible film COF. The low potential power line VSSL is disposed to surround the display area AA and may transmit a low potential power voltage to the display area AA. The low potential power line VSSL may be disposed along the edges EG1, EG2, EG3, and EG4 of the display device 100 and may have a shape corresponding to the edges EG1, EG2, EG3, and EG4 of the display device 100.

Accordingly, the display device 100 is applied to various products and may be formed in a heterogeneous shape, and configurations such as the gate driver GD, the flexible film COF, and the low potential power line VSSL may be disposed to correspond to the heterogeneous shape.

Meanwhile, the display panel PN of the display device 100 according to the example embodiment of the present disclosure may have a touch on Encap (TOE) structure in which the touch unit 150 is directly formed on the encapsulation layer 140. The display panel PN may include the touch unit 150 to sense a touch input.

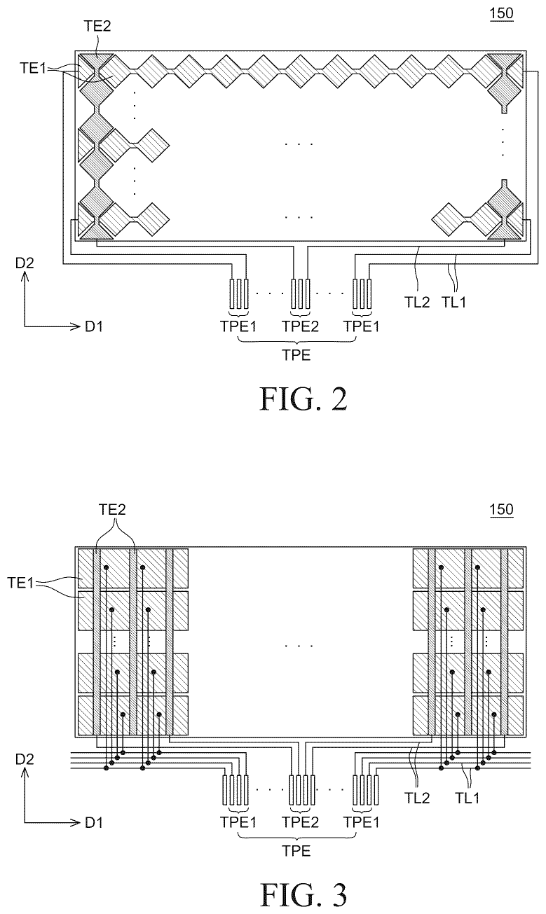

The touch unit 150 may have various structures according to a touch sensing method and a signal input method. Hereinafter, the configuration of the touch unit 150 will be described first with reference to FIGS. 2 and 3.

FIGS. 2 and 3 are schematic plan views of a touch unit of a display device according to an example embodiment of the present disclosure. Specifically, FIG. 2 is a schematic plan view of a touch unit 150 having a dual feeding structure, and FIG. 3 is a schematic plan view of a touch unit 150 having a multi feeding structure.

Touch unit 150 may sense a touch input in a mutual-capacitance method or a self-capacitance method. The mutual capacitance method senses a touch input based on a change in capacitance between the touch driving electrode and the touch sensing electrode. The self-capacitance method senses a touch input based on a change in capacitance between an external input and a touch electrode.

Hereinafter, the description will be made on the assumption that the touch unit 150 of the display device 100 according to the example embodiment of the present disclosure is the touch unit 150 that may be used by integrating a mutual-capacitance method and a self-capacitance method.

As shown in FIGS. 2 and 3, the touch unit 150 includes a plurality of touch lines TL and a plurality of touch electrodes TE. The plurality of touch lines TL includes a plurality of first touch lines TL1 and a plurality of second touch lines TL2, and the plurality of touch electrodes TE includes a plurality of first touch electrodes TE1 and a plurality of second touch electrodes TE2. In this case, as illustrated in FIGS. 2 and 3, the shape and arrangement of the plurality of touch electrodes TE of the touch unit 150 and the connection structure of the touch electrode TE and the touch line TL may be configured in various ways.

For example, as shown in FIG. 2, the plurality of first touch electrodes TE1 may be arranged in a matrix form at regular intervals. The plurality of first touch electrodes TE1 may have a rhombic shape. Further, first touch electrodes TE1 on the same line arranged along the first direction D1 among the plurality of first touch electrodes TE1 may be connected to each other. For example, the first touch electrodes TE1 in the n-th row may be electrically connected to each other to form a line of one first touch electrode TE1.

The plurality of second touch electrodes TE2 may be arranged in a matrix form at regular intervals. The plurality of second touch electrodes TE2 may have a rhombic shape. The plurality of second touch electrodes TE2 may be alternately disposed with the plurality of first touch electrodes TE1. The second touch electrodes TE2 of the same line arranged in the second direction D2 among the plurality of second touch electrodes TE2 may be connected. For example, the second touch electrodes TE2 in the n-th column may be electrically connected to each other to form a line of one second touch electrode TE2. Accordingly, the line of the first touch electrode TE1 and the line of the second touch electrode TE2 may cross each other.

The plurality of first touch lines TL1 is electrically connected to the plurality of first touch electrodes TE1. The plurality of first touch lines TL1 may be electrically connected to the first touch pad electrode TPE1 among the plurality of touch pad electrodes TPE and transmit a touch signal from the first touch pad electrode TPE1 to the plurality of first touch electrodes TE1. For example, the first touch line TL1 may be connected to both ends of a line of one first touch electrode TE1 composed of a plurality of first touch electrodes TE1 disposed on the same row. Signal delay may be minimized or reduced by supplying touch signals to both ends of the line of the first touch electrode TE1.

The plurality of second touch lines TL2 is electrically connected to the plurality of second touch electrodes TE2. The plurality of second touch lines TL2 may be electrically connected to the second touch pad electrode TPE2 among the plurality of touch pad electrodes TPE and may electrically connect the second touch pad electrode TPE2 and the plurality of second touch electrodes TE2. For example, the second touch line TL2 may be connected to one end of a line of the second touch electrode TE2 composed of a plurality of second touch electrodes TE2 disposed in the same column.

The touch unit 150 of FIG. 2 may have a dual-feeding structure in which signals are simultaneously applied to both ends of the line of the touch electrode TE. For example, as the size of the display device 100 increases, the length of the line of the touch electrode TE made of the same line of touch electrodes TE increases, and signal transmission may be delayed according to the position of the touch electrode TE. Therefore, to reduce the transmission/reception time deviation of the touch signal, one or more touch lines TL are connected to the same line constituting the line of the touch electrode TE to minimize or reduce the signal delay.

Next, as shown in FIG. 3, the plurality of first touch electrodes TE1 may be arranged in a matrix form at regular intervals. The plurality of first touch electrodes TE1 may have a rectangular shape. The first touch electrodes TE1 on the same line arranged along the first direction D1 among the plurality of first touch electrodes TE1 may be simultaneously applied with a signal. For example, a plurality of first touch pad electrodes TPE1 is disposed in the non-display area NA, and an n-th first touch line TL1 electrically connected to an n-th first touch pad electrode TPE1 among the plurality of first touch pad electrodes TPE1 may be connected to a plurality of first touch electrodes TE1 disposed on the same line.

The plurality of second touch electrodes TE2 may be disposed between the plurality of first touch electrodes TE1. The plurality of second touch electrodes TE2 may have a rectangular shape. For example, the plurality of first touch electrodes TE1 and the plurality of second touch electrodes TE2 may be alternately disposed in the first direction D1. The first touch electrode TE1 and the second touch electrode TE2 may be disposed on the same row, and the first touch electrode TE1 and the second touch electrode TE2 may be disposed in different columns. The second touch electrodes TE2 on the same line arranged in the second direction D2 among the plurality of second touch electrodes TE2 may be simultaneously applied with a signal. For example, a plurality of second touch pad electrodes TPE2 is disposed in the non-display area NA, and an n-th second touch line TL2 electrically connected to an n-th second touch pad electrode TPE2 among the plurality of second touch pad electrodes TPE2 may be connected to a plurality of second touch electrodes TE2 disposed on the same line.

The plurality of first touch lines TL1 is electrically connected to the plurality of first touch electrodes TE1. The plurality of first touch lines TL1 may be electrically connected to the first touch pad electrode TPE1 among the plurality of touch pad electrodes TPE and transmit a touch signal from the first touch pad electrode TPE1 to the plurality of first touch electrodes TE1.

The plurality of second touch lines TL2 is electrically connected to the plurality of second touch electrodes TE2. The plurality of second touch lines TL2 may be electrically connected to the second touch pad electrode TPE2 among the plurality of touch pad electrodes TPE and may electrically connect the second touch pad electrode TPE2 and the plurality of second touch electrodes TE2.

Meanwhile, the touch unit 150 of FIG. 3 may have a multi-feeding structure in which signals are simultaneously applied to the plurality of touch electrodes TE. For example, as the size of the display device 100 increases, the length of the line of the touch electrode TE made of the same line of touch electrodes TE increases, and signal transmission may be delayed according to the position of the touch electrode TE. Accordingly, to reduce the transmission/reception time deviation of the touch signal, the touch line TL may be connected to each of the plurality of touch electrodes TE of the same line constituting the line of the touch electrode TE to simultaneously apply a signal. Accordingly, the plurality of touch lines TL is connected to each of the plurality of touch electrodes TE one-to-one to reduce the delay of the touch signal and improve the touch performance for the entire area of the display device 100.

Further, the plurality of first touch electrodes TE1 may be touch driving electrodes, and the plurality of second touch electrodes TE2 may be touch sensing electrodes. Further, the plurality of first touch lines TL1 may be touch driving lines, and the plurality of second touch lines TL2 may be touch sensing lines. In this case, the touch driver TD may transmit a touch driving signal to the first touch electrode TE1 through the first touch line TL1, and receive a touch sensing signal from the second touch electrode TE2 through the second touch line TL2.

However, each of the first touch electrode TE1 and the first touch line TL1 may be a touch sensing electrode and a touch sensing line, and each of the second touch electrode TE2 and the second touch line TL2 may be a touch driving electrode and a touch driving line, but the example embodiments of the present disclosure are not limited thereto.

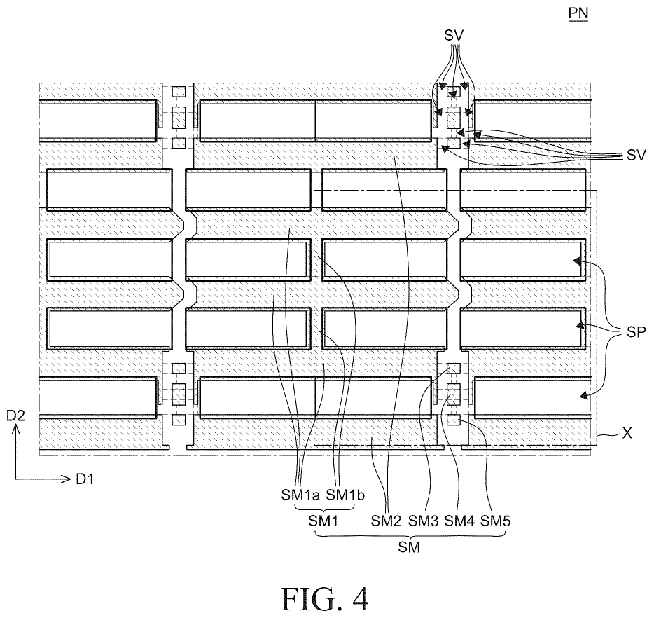

Hereinafter, a detailed structure of the sub-pixel SP and the touch unit 150 of the display panel PN will be described with reference to FIGS. 4 to 8B.

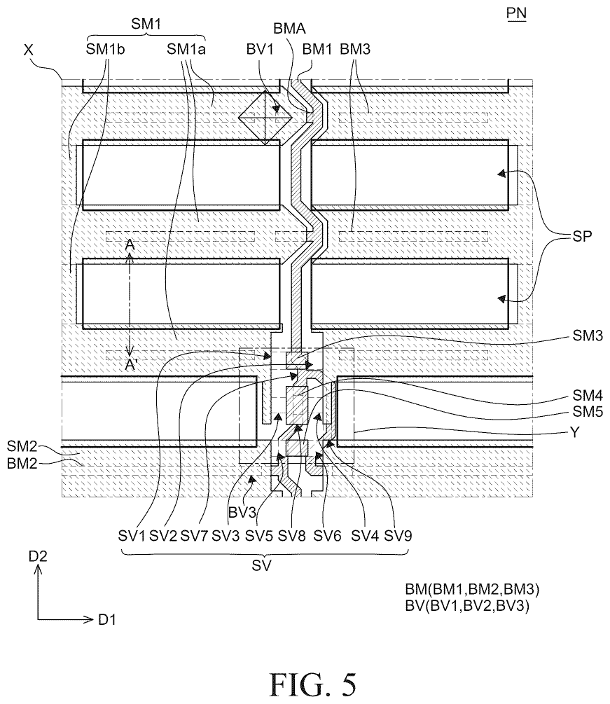

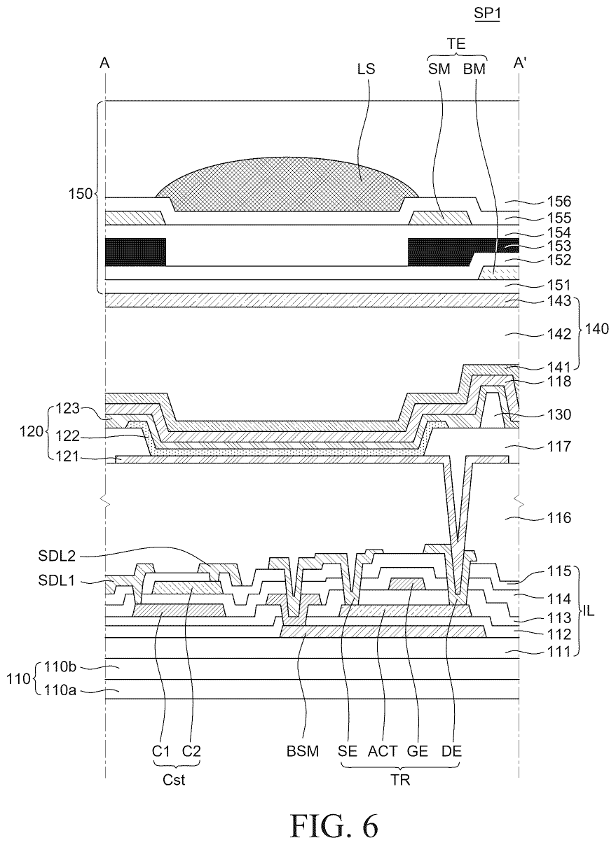

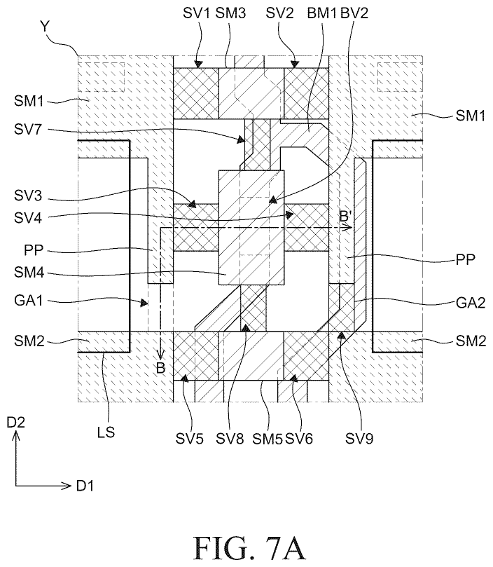

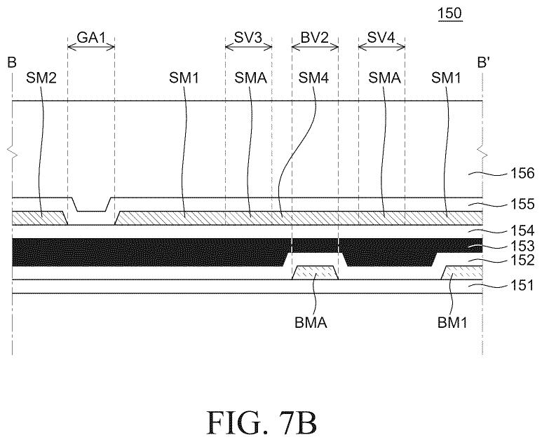

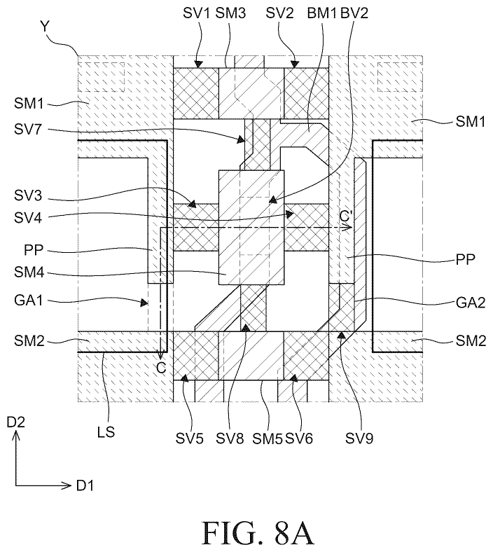

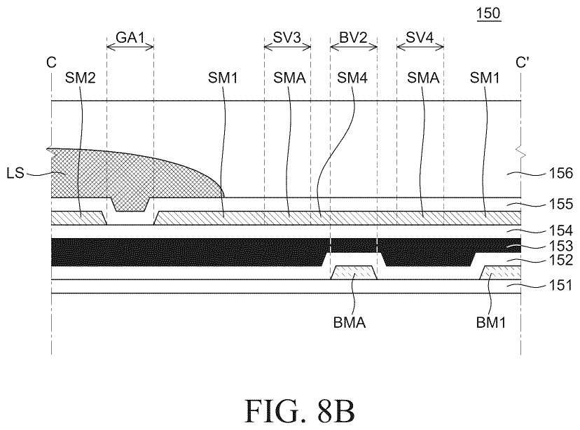

FIG. 4 is an enlarged plan view of a display device according to an example embodiment of the present disclosure. FIG. 5 is an example enlarged plan view of an area X of FIG. 4. FIG. 6 is a cross-sectional view taken along the line A-A′ in FIG. 5. FIG. 7A is an example enlarged plan view of an area Y of FIG. 5. FIG. 7B is a cross-sectional view taken along the line B-B′ in FIG. 7A. FIG. 8A is an example enlarged plan view of an area Y of FIG. 5. FIG. 8B is a cross-sectional view taken along line C-C′ in FIG. 8A. FIGS. 7A and 8A illustrate a case in which the additional sensor metal SMA is disposed in all of the plurality of sensor variable regions SV. For convenience of description, only the configuration of the touch unit 150 is illustrated in FIGS. 7B and 8B.

As shown in FIGS. 4 and 5, the display panel PN includes a plurality of sub-pixels SP. The plurality of sub-pixels SP may be disposed along each of the first direction D1 and the second direction D2. The plurality of sub-pixels SP may include a red sub-pixel, a green sub-pixel, and a blue sub-pixel.

As shown in FIG. 6, the substrate 110 is a support member for supporting other components of the display device 100 and may be formed of an insulating material. For example, the substrate 110 may be made of glass, resin, or the like.

The substrate 110 may be formed of one or more layers. For example, the substrate 110 may have a double-layer structure including a first substrate 110a and a second substrate 110b on the first substrate 110a. For example, the first substrate 110a and the second substrate 110b may be formed of polyimide (PI). Further, although not illustrated in the drawings, an insulating layer may be further disposed between the first substrate 110a and the second substrate 110b.

An insulating layer group IL is disposed on the substrate 110. The insulating layer group IL may include at least one inorganic insulating layer. For example, the insulating layer group IL may include a multi-buffer layer 111, an active buffer layer 112, a gate insulating layer 113, a first interlayer insulating layer 114, and a second interlayer insulating layer 115.

First, the multi-buffer layer 111 is disposed on the substrate 110. The multi-buffer layer 111 may reduce penetration of moisture or impurities through the substrate 110. For example, the multi-buffer layer 111 may be configured by a single layer or a double layer of an insulating material such as silicon nitride (SiNₓ), silicon oxide (SiOₓ), and silicon oxynitride (SiON), but is not limited thereto.

The light shielding layer BSM is disposed on the multi-buffer layer 111. The light shielding layer BSM blocks light incident onto the active layer ACT of the transistor TR below the substrate 110 to minimize or reduce a leakage current of the plurality of transistors TR. Further, the light shielding layer BSM may minimize or reduce damage to the plurality of transistors TR due to charges trapped in the substrate 110. The light shielding layer BSM is connected to the source electrode SE or the drain electrode DE of the transistor TR to minimize or reduce an influence on the threshold voltage of the transistor TR. The light shielding layer BSM may be formed of a single layer or a multi-layer formed of any one of molybdenum (Mo), copper (Cu), titanium (Ti), aluminum (Al), chrome (Cr), gold (Au), nickel (Ni), and neodymium (Nd) or an alloy thereof, but is not limited thereto.

The active buffer layer 112 is disposed on the light shielding layer BSM. The active buffer layer 112 may protect the transistor TR from impurities such as alkali ions discharged from the substrate 110. In addition, the active buffer layer 112 may improve adhesion between layers formed on the active buffer layer 112 and the substrate 110. For example, the active buffer layer 112 may be configured by a single layer or a double layer of an insulating material, such as silicon nitride (SiNₓ), silicon oxide (SiOₓ), and silicon oxynitride (SiON), but is not limited thereto.

The transistor TR is disposed on the active buffer layer 112. The transistor TR includes an active layer ACT, a gate electrode GE, a source electrode SE, and a drain electrode DE.

First, the active layer ACT is disposed on the active buffer layer 112. The active layer ACT may be formed of a semiconductor material such as an oxide semiconductor, amorphous silicon, or polysilicon, but is not limited thereto.

The gate insulating layer 113 is disposed on the active layer ACT. The gate insulating layer 113 is an insulating layer which insulates the active layer ACT from the gate electrode GE and may be configured by a single layer or a double layer of silicon oxide (SiOₓ) or silicon nitride (SiNₓ), but is not limited thereto.

The gate electrode GE is disposed on the gate insulating layer 113. The gate electrode GE may be a single layer or multiple layers formed of a conductive material, for example, any one of molybdenum (Mo), aluminum (Al), chromium (Cr), gold (Au), titanium (Ti), nickel (Ni), neodymium (Nd), and copper (Cu) or an alloy thereof, but is not limited thereto.

The first interlayer insulating layer 114 is disposed on the gate electrode GE, and the second interlayer insulating layer 115 is disposed on the first interlayer insulating layer 114. The first interlayer insulating layer 114 and the second interlayer insulating layer 115 are insulating layers which protect components therebelow and may be configured by a single layer or a double layer of silicon oxide (SiOₓ) or silicon nitride (SiNₓ), but are not limited thereto.

The source electrode SE and the drain electrode DE are disposed on the second interlayer insulating layer 115. The source electrode SE and the drain electrode DE may be electrically connected to the active layer ACT through contact holes formed in the second interlayer insulating layer 115, the first interlayer insulating layer 114, and the gate insulating layer 113. The source electrode SE and the drain electrode DE may be configured as a single layer or multilayer structure of a conductive material, such as copper (Cu), aluminum (Al), molybdenum (Mo), nickel (Ni), titanium (Ti), gold (Au), chrome (Cr), or an alloy thereof, but are not limited thereto.

The capacitor Cst is disposed on the gate insulating layer 113. The capacitor Cst may include a first capacitor electrode C1 and a second capacitor electrode C2. The first capacitor electrode C1 may be disposed on the gate insulating layer 113, and the second capacitor electrode C2 may be disposed on the first interlayer insulating layer 114. The first capacitor electrode C1 and the second capacitor electrode C2 may overlap each other with the first interlayer insulating layer 114 interposed therebetween. For example, the first capacitor electrode C1 and the second capacitor electrode C2 may be a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but are not limited thereto.

Meanwhile, various conductive layers may be further disposed on the substrate 110. Various conductive layers may constitute any one of a plurality of lines, a plurality of transistors TR, and a plurality of capacitors Cst. For example, the first conductive layer SDL1 and the second conductive layer SDL2 may be disposed on the second interlayer insulating layer 115. The first conductive layer SDL1 may be connected to the first capacitor electrode C1, and the second conductive layer SDL2 may be connected to the second capacitor electrode C2. Each of the first conductive layer SDL1 and the second conductive layer SDL2 may function as an electrode connecting the first capacitor electrode C1 and the second capacitor electrode C2 to another configuration of the sub-pixel SP.

A planarization layer 116 is disposed on the transistor TR. The planarization layer 116 is an insulating layer that planarizes an upper portion of the substrate 110. The planarization layer 116 may be formed of an organic material, and for example, may be configured by a single layer or a double layer of an organic material such as polyimide or photo acryl, but is not limited thereto.

The light-emitting element 120 is disposed on the planarization layer 116. The light-emitting element 120 may be an organic light-emitting diode (OLED). The light-emitting element 120 includes an anode 121, a light-emitting layer 122, and a cathode 123.

The anode 121 is disposed on the planarization layer 116. The anode 121 may be connected to the drain electrode DE of the transistor TR. The anode 121 may be formed of a conductive material having a high work function to supply holes to the light emitting layer 122. For example, the anode 121 may be formed of a transparent conductive material such as indium tin oxide (ITO) or indium zinc oxide (IZO), but is not limited thereto.

Meanwhile, the display device 100 may be implemented as a top emission or bottom emission type. In the case of the top emission type, a reflective layer for reflecting light emitted from the light emitting layer 122 toward the cathode 123 may be disposed below the anode 121. For example, the reflective layer may include a material having excellent reflectivity, such as aluminum (Al) or silver (Ag), but is not limited thereto. Conversely, in the case of the bottom emission type, the anode 121 may be made of only a transparent conductive material. Hereinafter, the description will be made on the assumption that the display device 100 according to the example embodiment of the present disclosure is a top emission type.

The bank 117 is disposed on the anode 121 and the planarization layer 116. The bank 117 may cover an edge of the anode 121. The bank 117 divides the plurality of sub-pixels SP and may prevent or suppress color mixture between the plurality of sub-pixels SP. The bank 117 may be an organic insulating material. For example, the bank 117 may be formed of any one of polyimide, acryl, or benzocyclobutene (BCB)-based resin, but is not limited thereto.

The spacer 130 is disposed on the bank 117. It is possible to prevent or suppress damage to the light-emitting element 120 that may occur when a fine metal mask (FMM) used to form the light-emitting layer 122 of the light-emitting element 120 directly contacts the bank 117 or the anode 121. The spacer 130 may be formed of the same material as the bank 117 or formed of an insulating material different from the bank 117, but is not limited thereto. Further, the spacer 130 and the bank 117 may be integrally formed at one time. As the spacer 130 is disposed on the bank 117, the cathode 123 may be disposed to cover the spacer 130 and the bank 117.

The light emitting layer 122 is disposed on the anode 121 and the bank 117. The light emitting layer 122 may be an organic layer for emitting light of a specific color. The light emitting layer 122 may further include various layers such as a hole transport layer, a hole injection layer, a hole blocking layer, an electron injection layer, an electron blocking layer, and an electron transport layer. The light emitting layer 122 may be separately formed for each sub-pixel SP to emit different color light for each sub-pixel SP. For example, the light emitting layer 122 for red (Red), the light emitting layer 122 for green (Green), and the light emitting layer 122 for blue (Blue) may be separately formed in each sub-pixel SP. In contrast, the light-emitting layers 122 which emit white light are commonly formed in the plurality of sub-pixels SP, and a light conversion member which converts white light into light of various colors may be separately provided, and the example embodiments of the present disclosure are not limited thereto.

The cathode 123 is disposed on the light emitting layer 122. The cathode 123 may be formed as one layer over the entire surface of the substrate 110. That is, the cathode 123 may be a common layer commonly formed in the plurality of sub-pixels SP. Since the cathode 123 supplies electrons to the light emitting layer 122, the cathode 123 may be formed of a conductive material having a low work function. The cathode 123 may be formed of, for example, a transparent conductive material such as indium tin oxide (ITO) or indium zinc oxide (IZO), a metal alloy such as MgAg or an ytterbium (Yb) alloy, and may further include a metal doping layer, but is not limited thereto.

The protection layer 118 is disposed on the cathode 123. The protection layer 118 may protect the light emitting element 120 so that foreign matter or moisture does not penetrate into the light emitting element 120. For example, the protection layer 118 may be formed of an inorganic material such as aluminum oxide (Al₂O₃) or silicon nitride (SiNₓ).

The encapsulation layer 140 is disposed on the protection layer 118. The encapsulation layer 140 may protect the light emitting element 120 from moisture permeating from the outside of the display device 100. The encapsulation layer 140 includes a first inorganic encapsulation layer 141, an organic encapsulation layer 142, and a second inorganic encapsulation layer 143.

The first inorganic encapsulation layer 141 is disposed on the protection layer 118, and the second inorganic encapsulation layer 143 is disposed on the first inorganic encapsulation layer 141. The first inorganic encapsulation layer 141 and the second inorganic encapsulation layer 143 may serve to block the penetration of moisture or oxygen. The first inorganic encapsulation layer 141 and the second inorganic encapsulation layer 143 may be formed of an inorganic material, for example, an inorganic material such as silicon nitride (SiNₓ), silicon oxide (SiOₓ), or aluminum oxide (AlOₓ), but are not limited thereto.

The organic encapsulation layer 142 is disposed between the first inorganic encapsulation layer 141 and the second inorganic encapsulation layer 143. The organic encapsulation layer 142 may be formed to have a greater thickness than the first inorganic encapsulation layer 141 and the second inorganic encapsulation layer 143 to adsorb and block particles that may be generated during the manufacturing process of the display device 100. The organic encapsulation layer 142 may fill cracks that may occur in the first inorganic encapsulation layer 141 and the second inorganic encapsulation layer 143, and cover foreign substances on the first inorganic encapsulation layer 141 to planarize the upper portion. The organic encapsulation layer 142 may be formed of an organic material, for example, an epoxy-based or acryl-based polymer, but is not limited thereto.

The touch unit 150 is disposed on the encapsulation layer 140. Touch unit 150 may sense an external touch input using a user's finger or a touch pen. The touch unit 150 includes a touch buffer layer 151, a first touch insulating layer 152, a black matrix 153, a second touch insulating layer 154, a third touch insulating layer 155, a touch protection layer 156, a touch electrode TE composed of a bridge metal BM, and a sensor metal SM, and a lens LS.

First, the touch buffer layer 151 is disposed on the encapsulation layer 140. The touch buffer layer 151 is an insulating layer for protecting surrounding components such as the encapsulation layer 140 and the light emitting element 120 during the process of forming the touch unit 150. The touch buffer layer 151 may minimize or reduce the permeation of moisture from the outside, a material used in the manufacturing process of the touch unit 150, and the like into the light emitting element 120. For example, the touch buffer layer 151 may be formed of an insulating material such as silicon oxide (SiOₓ) or silicon nitride (SiNₓ), but is not limited thereto.

A plurality of bridge metals BM are disposed on the touch buffer layer 151. The plurality of bridge metals BM are metals constituting the touch electrode TE and may be disposed between the plurality of sub-pixels SP. For example, the bridge metal BM may constitute the touch electrode TE together with the sensor metal SM, or may constitute the bridge electrode at an intersection between the first touch electrode TE1 and the second touch electrode TE2. For example, any one of the first touch electrode TE1 and the second touch electrode TE2 is configured by a bridge metal BM, that is, a bridge electrode, in the crossing area of the touch electrode TE, such that the first touch electrode TE1 and the second touch electrode TE2 may be separated. For example, the bridge metal BM may be formed of a metal material such as copper (Cu), aluminum (Al), titanium (Ti), chromium (Cr), nickel (Ni) or a stacked structure of metal materials such as titanium/aluminum/titanium (Ti/Al/Ti), but is not limited thereto.

The first touch insulating layer 152 is disposed on the plurality of bridge metals BM. The first touch insulating layer 152 is an insulating layer which protects the bridge metal BM and insulates the bridge metal BM from the sensor metal SM. For example, the first touch insulating layer 152 may be formed of an insulating material such as silicon oxide (SiOₓ) or silicon nitride (SiNₓ), but is not limited thereto.

The black matrix 153 is disposed on the first touch insulating layer 152. The black matrix 153 may include an opening overlapping the plurality of light emitting elements 120, and light emitted from the light emitting elements 120 may be directed to the outside of the display device 100. The black matrix 153 may shield light of each of the plurality of sub-pixels SP so as not to be mixed with each other. In addition, the black matrix 153 absorbs light incident from the outside to the display device 100, thereby minimizing or reducing a decrease in visibility due to the reflection of external light from the configuration inside the display device 100. For example, the black matrix 153 includes a black component and may be made of an opaque resin including a pigment, but is not limited thereto.

The second touch insulating layer 154 is disposed on the black matrix 153. The second touch insulating layer 154 may planarize an upper portion of the black matrix 153. For example, the second touch insulating layer 154 may be configured by a single layer or a double layer of an organic material, such as polyimide or photo acryl, but is not limited thereto.

A plurality of sensor metals SM are disposed on the second touch insulating layer 154. The plurality of sensor metals SM is metals constituting the touch electrode TE and may be disposed between the plurality of sub-pixels SP. For example, the sensor metal SM may constitute the touch electrode TE together with the bridge metal BM. For example, the sensor metal SM may be formed of a metal material such as copper (Cu), aluminum (Al), titanium (Ti), chromium (Cr), and nickel (Ni) or a stacked structure of metal materials such as titanium/aluminum/titanium (Ti/Al/Ti), but is not limited thereto.

The third touch insulating layer 155 is disposed on the plurality of sensor metals SM. The third touch insulating layer 155 may protect the bridge metal BM and the sensor metal SM from external moisture or the like. For example, the third touch insulating layer 155 may be formed of an insulating material such as silicon oxide (SiOₓ) or silicon nitride (SiNₓ), but is not limited thereto.

The lens LS is disposed on the third touch insulating layer 155 in each of the plurality of sub-pixels SP. The lens LS may be disposed to overlap the openings of the light-emitting element 120 and the black matrix 153 to control a viewing angle of light from the light-emitting element 120. The lens LS may be a half-cylindrical lens LS and may have a rectangular cross section in the longitudinal direction of the lens LS and a half-circular cross section in the width direction. Accordingly, the lens LS limits the viewing angle in the width direction and does not limit the viewing angle in the length direction of the lens LS.

In the display device 100 according to the example embodiment of the present disclosure, the longitudinal direction of the lens LS is the same as the first direction D1, and the width direction of the lens LS is disposed in the same manner as the second direction D2. Therefore, a viewing angle in the left and right directions, which is a viewing angle in the first direction D1, is not limited, and a viewing angle in the vertical direction, which is a viewing angle in the second direction D2, may be limited within a predetermined range. Accordingly, the lens LS may protect information by limiting the viewing angle so that the image is viewed smoothly only within a certain range of viewing angles in the vertical direction from the front of the display panel PN.

The touch protection layer 156 is disposed on the lens LS. The touch protection layer 156 may protect the plurality of touch electrodes TE and the lens LS from external moisture or impact. For example, the touch protection layer 156 may be made of an organic material such as an epoxy-based or acryl-based polymer, but is not limited thereto.

Meanwhile, as shown in FIGS. 4 and 5, the plurality of sensor metals SM which configures the touch electrode TE may include a plurality of first sensor metals SM1, a plurality of second sensor metals SM2, a plurality of third sensor metals SM3, a plurality of fourth sensor metals SM4, and a plurality of fifth sensor metals SM5.

First, the plurality of first sensor metals SM1 may be disposed in a matrix while forming a plurality of rows and a plurality of columns. Each of the plurality of first sensor metals SM1 may include a plurality of first portions SM1a extending in the first direction D1 between the plurality of sub-pixels SP, and a plurality of second portions SM1b extending in the second direction D2 between the plurality of sub-pixels SP and connecting the plurality of first portions SM1a to each other. For example, the first sensor metal SM1 may include three first portions SM1a and may be formed of two second portions SM1b connecting the first portions SM1a between the three first portions SM1a. In the second direction D2, the sub-pixels SP may be disposed on both sides of the first portion SM1a, and in the first direction D1, the sub-pixels SP may be disposed on both sides of the second portion SM1b. However, the number of the first portion SM1a and the second portion SM1b forming the first sensor metal SM1 may vary, but is not limited thereto.

The plurality of second sensor metals SM2 may be disposed in a matrix while forming a plurality of rows and a plurality of columns. The plurality of first sensor metals SM1 and the plurality of second sensor metals SM2 may be alternately disposed along the second direction D2. The plurality of first sensor metals SM1 and the plurality of second sensor metals SM2 may be alternately disposed in the same column. The row in which the plurality of first sensor metals SM1 is disposed and the row in which the plurality of second sensor metals SM2 is disposed may be alternately disposed.

Next, the third sensor metal SM3, the fourth sensor metal SM4, and the fifth sensor metal SM5 may be disposed between the pair of first sensor metals SM1 adjacent to each other in the first direction D1. The third sensor metal SM3 and the fourth sensor metal SM4 may be disposed adjacent to the lower first portion SM1a of the plurality of first portions SM1a of the first sensor metal SM1. The fifth sensor metal SM5 may be disposed adjacent to the second sensor metal SM2. The third sensor metal SM3, the fourth sensor metal SM4, and the fifth sensor metal SM5 may be sequentially disposed along the second direction D2. A pair of first sensor metals SM1 adjacent to each other may be connected to each other by using the third sensor metal SM3 and the fourth sensor metal SM4 and the sensor variable region SV, and a pair of second sensor metals SM2 adjacent to each other may be connected to each other by using the fifth sensor metal SM5 and the sensor variable region SV. In addition, the first sensor metal SM1 and the second sensor metal SM2 may be connected to each other by using the third sensor metal SM3, the fourth sensor metal SM4, the fifth sensor metal SM5, and the sensor variable region SV, which will be described in more detail below.

Next, as shown in FIGS. 4 and 5 together, a plurality of bridge metals BM may be disposed between the plurality of sensor metals SM. The plurality of bridge metals BM may connect some of the plurality of sensor metals SM to each other and may function as a touch electrode TE together with the sensor metal SM.

The plurality of bridge metals BM may include a plurality of first bridge metals BM1, a plurality of second bridge metals BM2, and a plurality of third bridge metals BM3.

The plurality of first bridge metals BM1 may extend in the second direction D2 in the area between the plurality of sub-pixels SP. The plurality of first bridge metals BM1 may be disposed between the first sensor metal SM1 and the second sensor metal SM2. Each of the plurality of first bridge metals BM1 may be electrically connected to the first sensor metal SM1 through an additional bridge metal BMA of the first bridge variable region BV1. The plurality of first bridge metals BM1 disposed in the same column may be disposed to be spaced apart from each other with the second bridge variable region BV2 interposed therebetween.

The plurality of second bridge metals BM2 may extend in the first direction D1 in the area between the plurality of sub-pixels SP. Each of the plurality of second bridge metals BM2 may overlap the second sensor metal SM2. Both ends of each of the plurality of second bridge metals BM2 may face the first bridge metal BM1 with the third bridge variable region BV3 interposed therebetween.

The plurality of third bridge metals BM3 may extend in the first direction D1 in the area between the plurality of sub-pixels SP. Each of the plurality of third bridge metals BM3 may overlap the first portion SM1a of the first sensor metal SM1. The plurality of third bridge metals BM3 may have an island shape.

Meanwhile, the plurality of sensor metals SM may be separated from each other with the sensor variable region SV interposed therebetween, and the plurality of bridge metals BM may be separated from each other with the bridge variable region BV interposed therebetween. Further, a metal is selectively formed in each of the sensor variable region SV and the bridge variable region BV to connect some of the sensor metals SM to each other or connect some of the bridge metals BM to each other. Accordingly, the connection structure between the sensor metal SM and the bridge metal BM may be variously configured using the metal of the sensor variable region SV and the bridge variable region BV.

Specifically, as shown in FIG. 5, and 7A to 8B together, a plurality of sensor variable regions SV are disposed between a plurality of sensor metals SM. The plurality of sensor variable regions SV is regions in which the additional sensor metal SMA is selectively disposed. The plurality of sensor variable regions SV may be disposed in an area between the plurality of lenses LS, that is, an area between the plurality of sub-pixels SP.

The plurality of sensor variable regions SV includes a first sensor variable region SV1, a second sensor variable region SV2, a third sensor variable region SV3, a fourth sensor variable region SV4, a fifth sensor variable region SV5, a sixth sensor variable region SV6, a seventh sensor variable region SV7, an eighth sensor variable region SV8, and a ninth sensor variable region SV9.

The first sensor variable region SV1 to the ninth sensor variable region SV9 disposed adjacent to each other between the first sensor metal SM1 and the second sensor metal SM2 may form a group of the sensor variable regions SV.

The first sensor variable region SV1 is disposed on one side of the third sensor metal SM3, and the second sensor variable region SV2 is disposed on the other side of the third sensor metal SM3. Each of the first sensor variable region SV1 and the second sensor variable region SV2 may be disposed between the first sensor metal SM1 and the third sensor metal SM3. The first sensor variable region SV1 and the second sensor variable region SV2 may be variable regions for connecting the third sensor metal SM3 to the first sensor metal SM1 on both sides of the third sensor metal SM3. The additional sensor metal SMA is formed in the first sensor variable region SV1 to connect the third sensor metal SM3 and the first sensor metal SM1 at one side of the third sensor metal SM3. The additional sensor metal SMA is formed in the second sensor variable region SV2 to connect the third sensor metal SM3 and the first sensor metal SM1 at the other side of the third sensor metal SM3.

The third sensor variable region SV3 is disposed on one side of the fourth sensor metal SM4, and the fourth sensor variable region SV4 is disposed on the other side of the fourth sensor metal SM4. Each of the third sensor variable region SV3 and the fourth sensor variable region SV4 may be disposed between the first sensor metal SM1 and the fourth sensor metal SM4. The third sensor variable region SV3 and the fourth sensor variable region SV4 may be variable regions for connecting the fourth sensor metal SM4 to the first sensor metal SM1 on both sides of the fourth sensor metal SM4. The additional sensor metal SMA is formed in the third sensor variable region SV3 to connect the fourth sensor metal SM4 and the first sensor metal SM1 at one side of the fourth sensor metal SM4. The additional sensor metal SMA is formed in the fourth sensor variable region SV4 to connect the fourth sensor metal SM4 and the first sensor metal SM1 at the other side of the fourth sensor metal SM4.

The fifth sensor variable region SV5 is disposed on one side of the fifth sensor metal SM5, and the sixth sensor variable region SV6 is disposed on the other side of the fifth sensor metal SM5. Each of the fifth sensor variable region SV5 and the sixth sensor variable region SV6 may be disposed between the second sensor metal SM2 and the fifth sensor metal SM5. The fifth sensor variable region SV5 and the sixth sensor variable region SV6 may be variable regions for connecting the fifth sensor metal SM5 to the second sensor metal SM2 on both sides of the fifth sensor metal SM5. The additional sensor metal SMA is formed in the fifth sensor variable region SV5 to connect the fifth sensor metal SM5 and the second sensor metal SM2 at one side of the fifth sensor metal SM5. The additional sensor metal SMA is formed in the sixth sensor variable region SV6 to connect the fifth sensor metal SM5 and the second sensor metal SM2 at the other side of the fifth sensor metal SM5.

The seventh sensor variable region SV7 is disposed between the third sensor metal SM3 and the fourth sensor metal SM4. The additional sensor metal SMA is formed in the seventh sensor variable region SV7 to connect the third sensor metal SM3 and the fourth sensor metal SM4.

The eighth sensor variable region SV8 is disposed between the fourth sensor metal SM4 and the fifth sensor metal SM5. The additional sensor metal SMA is formed in the eighth sensor variable region SV8 to connect the fourth sensor metal SM4 and the fifth sensor metal SM5 to each other.

The ninth sensor variable region SV9 may be disposed between the first sensor metal SM1 and the second sensor metal SM2. The ninth sensor variable region SV9 may be disposed between a portion protruding from one end of the first sensor metal SM1 toward the second sensor metal SM2 and the second sensor metal SM2. The additional sensor metal SMA is formed in the ninth sensor variable region SV9 to connect the first sensor metal SM1 and the second sensor metal SM2 to each other.

As shown in FIGS. 5, 7A, and 8B, the bridge variable region BV includes a first bridge variable region BV1, a second bridge variable region BV2, and a third bridge variable region BV3.

The first bridge variable region BV1 may extend from the first bridge metal BM1 in the first direction D1 and overlap the first sensor metal SM1. For example, the first bridge variable region BV1 may overlap the first sensor metal SM1 on the left side of the first bridge metal BM1. The additional bridge metal BMA may be formed in the first bridge variable region BV1, and the additional bridge metal BMA and the first sensor metal SM1 may be connected to each other through the contact holes of the second touch insulating layer and the black matrix. Accordingly, the first bridge metal BM1 may be connected to the first sensor metal SM1 on the left side of the first bridge metal BM1 through the additional bridge metal BMA.

The second bridge variable region BV2 is disposed between the first bridge metal BM1 and the first bridge metal BM1. The second bridge variable region BV2 may overlap the fourth sensor metal SM4. The additional bridge metal BMA may be formed in the second bridge variable region BV2 to connect the first bridge metals BM1 adjacent to each other.

The third bridge variable region BV3 is disposed between the first bridge metal BM1 and the second bridge metal BM2. The third bridge variable region BV3 may overlap the second sensor metal SM2. The additional bridge metal BMA is formed in the third bridge variable region BV3 to connect the first bridge metal BM1 and the second bridge metal BM2 to each other.

Meanwhile, as shown in FIGS. 7A and 8A, the first portion SM1a, which is disposed above and below the plurality of first portions SM1a of the first sensor metal SM1, may be disposed adjacent to the second sensor metal SM2. In this case, the first portion SM1a, which is disposed at the lower side among the plurality of first portions SM1a, may include the protruding portion PP protruding from both end portions toward the second direction D2, that is, toward the second sensor metal SM2. Further, a first gap area GA1 and a second gap area GA2 may be formed between the protruding portion PP of the first sensor metal SM1 and the second sensor metal SM2.

Specifically, each of the pair of protruding portions PP of the first sensor metal SM1 may face the second sensor metal SM2 with the first gap area GA1 and the second gap area GA2 interposed therebetween. A first gap area GA1 may be formed between the protruding portion PP at one side of the first portion SM1a and the second sensor metal SM2, and a second gap area GA2 may be formed between the protruding portion PP at the other side of the first portion SM1a and the second sensor metal SM2. Further, the first gap area GA1 may be disposed on the left side of the eighth sensor variable region SV8, and the second gap area GA2 may be disposed on the right side of the eighth sensor variable region SV8. The second gap area GA2 may overlap the ninth sensor variable region SV9.

Meanwhile, as the additional sensor metal SMA is selectively disposed in the plurality of sensor variable regions SV, a pattern shape difference may occur between groups consisting of the first sensor variable region SV1 to the ninth sensor variable region SV9 depending on the presence or absence of the additional sensor metal SMA. Accordingly, the arrangement of the plurality of sensor variable regions SV in each group and the length and area ratio of the additional sensor metal SMA in each group are matched equally so that the overall shape difference of the sensor variable region SV group according to the presence or absence of the additional sensor metal SMA can be mitigated, and the pattern of the sensor variable region SV group can be suppressed from visually recognized.

The lens LS on the touch electrode TE may be disposed to overlap the sub-pixel SP. The edge of the lens LS may be disposed to correspond to the boundary of the sub-pixel SP, and at least a part of the edge of the lens LS may overlap the sensor metal SM. The lens LS may not overlap the sensor variable region SV. When the sensor variable region SV in which the additional sensor metal SMA is selectively disposed overlaps the lens LS, the lens LS covers at least a part of the additional sensor metal SMA in the sensor variable region SV, so it may be difficult to match the length and area ratio of the additional sensor metal SMA in each group equally. Accordingly, the lens LS and the sensor variable region SV may be formed at different positions.

However, the position of the lens LS may be shifted according to the process error. For example, the lens LS may be shifted along the first direction D1. Accordingly, in the display device 100 according to the example embodiment of the present disclosure, the sensor variable region SV may be configured in consideration of the shift range of the lens LS.

For example, as shown in FIGS. 7A and 7B, some of the plurality of lenses LS may be disposed to be spaced apart from the first gap area GA1. That is, the first gap area GA1 may be non-overlapping with some of the lenses LS of the plurality of lenses LS.

As another example, as shown in FIGS. 8A and 8B, some of the plurality of lenses LS may be shifted along the first direction D1 to overlap the first gap area GA1. The edge of the lens LS may be disposed in the first gap area GA1.

The range in which the position of the lens LS is shifted along the first direction D1 may be shifted from the area illustrated in FIG. 7A to the area illustrated in FIG. 8A, that is, within the area between the pair of protruding portions PP protruding from both ends of the first sensor metal SM1, to the first gap area GA1.

Among the first gap area GA1 and the second gap area GA2 between the first sensor metal SM1 and the second sensor metal SM2, the first gap area GA1 may overlap or do not overlap the lens LS depending on the process deviation. However, the second gap area GA2 may be an area that does not overlap the lens LS regardless of the process deviation. That is, in the display device 100 according to the example embodiment of the present disclosure, the first gap area GA1 may be an area affected by the process deviation of the lens LS.

Accordingly, in the display device 100 according to the example embodiment of the present disclosure, the first gap area GA1 affected by the process deviation of the lens LS among the areas between the first sensor metal SM1 and the second sensor metal SM2 is not used as the sensor variable region SV, but only the second gap area GA2 not affected by the process deviation may be used as the sensor variable region SV.

For example, among the first gap area GA1 and the second gap area GA2 between the first sensor metal SM1 and the second sensor metal SM2, the second gap area GA2 is configured as a ninth sensor variable region SV9, and an additional sensor metal SMA is formed in the ninth sensor variable region SV9 to electrically connect the first sensor metal SM1 and the second sensor metal SM2 to each other.

Further, the first gap area GA1 is not used as the sensor variable region SV, but is placed as an empty area, so that the pattern of the touch electrode TE according to the positional deviation of the lens LS may not be visually recognized. If it is assumed that the additional sensor metal SMA is disposed in the first gap area GA1 configured as the sensor variable region SV, a pattern shape difference of the sensor metal SM may occur between an area in which the additional sensor metal SMA and the lens LS overlap and an area in which the additional sensor metal SMA and the lens LS do not overlap, and the user may more easily recognize the pattern of the touch electrode TE due to the shape difference. Accordingly, in the display device 100 according to the example embodiment of the present disclosure, among the first gap area GA1 and the second gap area GA2 between the first sensor metal SM1 and the second sensor metal SM2, only the second gap area GA2, which is not affected by the positional deviation of the lens LS, is configured as the sensor variable region SV to connect the first sensor metal SM1 and the second sensor metal SM2. In other words, the sensor variable region SV may be separated from the expected arrangement area of the lens LS according to the process error so that the sensor variable region SV and the lens LS do not overlap. The first gap area GA1 overlapping the expected arrangement area of the lens LS in consideration of the process error is placed as an empty space to reduce the difference in the pattern shape of the sensor metal SM according to the positional deviation of the lens LS and prevent or suppress the pattern of the touch electrode TE from being visually recognized by the user.

Example embodiments of the present disclosure can also be described as follows:

According to an aspect of the present disclosure, a display device includes a substrate including a plurality of sub-pixels. The display device further includes a light emitting element disposed in each of the plurality of sub-pixels. The display device further includes an encapsulation layer disposed on the light emitting element. The display device further includes a touch unit disposed on the encapsulation layer. The touch unit includes a black matrix which is disposed on the encapsulation layer and has a plurality of openings which overlaps the plurality of sub-pixels, a plurality of sensor metals disposed on the black matrix, and a plurality of lenses which is disposed on the plurality of sensor metals and overlaps the plurality of sub-pixels, and a plurality of sensor variable regions disposed between the plurality of sensor metals. The plurality of sensor variable regions are disposed in an area between the plurality of lenses.

According to another feature of the present disclosure, the plurality of lenses may be half-cylindrical lenses.

According to still another feature of the present disclosure, the plurality of lenses may have a rectangular cross section in the longitudinal direction and a semicircular cross section in the width direction, and the plurality of lenses may be configured to limit the viewing angle in the width direction.

According to still another feature of the present disclosure, the plurality of lenses may overlap the plurality of openings of the black matrix, respectively.

According to still another feature of the present disclosure, the touch unit may further include a touch buffer layer disposed on the encapsulation layer, a plurality of bridge metals disposed between the touch buffer layer and the black matrix, a first touch insulating layer disposed between the plurality of bridge metals and the black matrix, a second touch insulating layer disposed between the black matrix and the plurality of sensor metals, a third touch insulating layer disposed between the plurality of sensor metals and the plurality of lenses, and a touch protection layer disposed on the third touch insulating layer and the plurality of lenses.

According to still another feature of the present disclosure, the plurality of sensor metals may include a plurality of first sensor metals including a plurality of first portions extending in a first direction between the plurality of sub-pixels and a plurality of second portions extending in a second direction different from the first direction between the plurality of sub-pixels and connecting the plurality of first portions to each other, a plurality of second sensor metals alternately disposed with the plurality of first sensor metals in the second direction, a plurality of third sensor metals disposed between the plurality of first sensor metals adjacent to each other in the first direction, a plurality of fourth sensor metals disposed adjacent to the plurality of third sensor metals in the second direction, and a plurality of fifth sensor metals disposed between the plurality of second sensor metals adjacent to each other in the first direction and disposed adjacent to the plurality of fourth sensor metals in the second direction.

According to still another feature of the present disclosure, each of the plurality of first sensor metals may further include a pair of protruding portions extending toward a corresponding second sensor metal, among the plurality of second senor metals, from both ends of a first portion facing the corresponding second sensor metal, among the plurality of first portions, and a first gap area and a second gap area may be disposed between each of the pair of protruding portions and the corresponding second sensor metal.

According to still another feature of the present disclosure, some of the plurality of lenses may overlap the first gap area, other lenses of the plurality of lenses may be disposed to be spaced apart from the first gap area, and the plurality of lenses may be disposed to be spaced apart from the second gap area.

According to still another feature of the present disclosure, the plurality of sensor variable regions may include a first sensor variable region disposed on one side of the third sensor metal, a second sensor variable region disposed on the other side of the third sensor metal, a third sensor variable region disposed on one side of the fourth sensor metal, a fourth sensor variable region disposed on the other side of the fourth sensor metal, a fifth sensor variable region disposed on one side of the fifth sensor metal, a sixth sensor variable region disposed on the other side of the fifth sensor metal, a seventh sensor variable region disposed between the third sensor metal and the fourth sensor metal, an eighth sensor variable region disposed between the fourth sensor metal and the fifth sensor metal, and a ninth sensor variable region overlapping the second gap area.

According to still another feature of the present disclosure, each of the first sensor variable region and the second sensor variable region may be disposed between the third sensor metal and the first sensor metal, each of the third sensor variable region and the fourth sensor variable region may be disposed between the fourth sensor metal and the first sensor metal, and each of the fifth sensor variable region and the sixth sensor variable region may be disposed between the fifth sensor metal and the second sensor metal.

According to still another feature of the present disclosure, the plurality of bridge metals may include a plurality of first bridge metals extending in a second direction from an area between the plurality of first sensor metals and the plurality of second sensor metals, a plurality of second bridge metals overlapping the plurality of second sensor metals, and a plurality of third bridge metals overlapping the plurality of first sensor metals.

According to still another feature of the present disclosure, the display device may further include a first bridge variable region disposed between a third bridge metal of some of the plurality of third bridge metals and the plurality of first bridge metals, a second bridge variable region disposed between each of the plurality of first bridge metals, and a third bridge variable region disposed between the plurality of first bridge metals and the plurality of second bridge metals. The plurality of first sensor metals and the plurality of first bridge metals may be connected to each other respectively through a contact hole in the first bridge variable region.

According to still another feature of the present disclosure, an additional sensor metal may be disposed in a part or all the plurality of sensor variable regions.

According to still another feature of the present disclosure, the ninth sensor variable region may be disposed between the first sensor metal and the second sensor metal.

According to still another feature of the present disclosure, an additional bridge metal may be disposed in at least one of the first bridge variable region, the second bridge variable region and the third bridge variable region.

According to still another feature of the present disclosure, the second bridge variable region may be overlapped with the fourth sensor metal, and the third bridge variable region may be overlapped with the second sensor metal.

According to an aspect of the present disclosure, a display device may comprise: a substrate including a plurality of sub-pixels; a light emitting element disposed in each of the plurality of sub-pixels; a plurality of sensor metals disposed on the light emitting element; a plurality of lenses disposed on the plurality of sensor metals and overlapped with the light emitting element; and a plurality of sensor variable regions disposed between the plurality of sensor metals, and an additional sensor metal is disposed in a part or all the plurality of sensor variable regions, wherein the plurality of sensor variable regions are not overlapped with the plurality of lenses.

According to still another feature of the present disclosure, the plurality of sensor metals may comprise: a plurality of first sensor metals arranged in a matrix form; and a plurality of second sensor metals alternately disposed with the plurality of first touch electrodes and arranged in a matrix form, wherein the plurality of sensor variable regions are disposed between the plurality of first sensor metals and the plurality of second sensor metals.

According to still another feature of the present disclosure, the display device may further comprise: a plurality of bridge metals connected the plurality of sensor metals to each other, wherein the plurality of bridge metals comprises: a plurality of first bridge metals disposed in an area between the plurality of first sensor metals and the plurality of second sensor metals; a plurality of second bridge metals overlapping the plurality of second sensor metals; and a plurality of third bridge metals overlapping the plurality of first sensor metals.

According to still another feature of the present disclosure, the display device may further comprise: a first bridge variable region extending from the plurality of first bridge metals and overlapped with the plurality of first bridge metals; a second bridge variable region disposed between each of the plurality of first bridge metals in the second direction; and a third bridge variable region disposed between the plurality of first bridge metals and the plurality of second bridge metals, and wherein an additional bridge metal is disposed in at least one of the first bridge variable region, the second bridge variable region and the third bridge variable region.

Although various example embodiments of the present disclosure have been described in detail with reference to the accompanying drawings, the present disclosure is not limited thereto and may be embodied in various forms without departing from the technical concept of the present disclosure. Therefore, these example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including a plurality of sub-pixels;
a light emitting element disposed in each of the plurality of sub-pixels;
an encapsulation layer disposed on the light emitting element; and
a touch unit disposed on the encapsulation layer,
wherein the touch unit includes:
a black matrix disposed on the encapsulation layer and having a plurality of openings overlapping the plurality of sub-pixels;
a plurality of sensor metals disposed on the black matrix;
a plurality of lenses disposed on the plurality of sensor metals and overlapping the plurality of sub-pixels; and
a plurality of sensor variable regions disposed between the plurality of sensor metals, and
wherein the plurality of sensor variable regions are disposed between the plurality of lenses.

2. The display device according to claim 1, wherein the plurality of lenses are semi-cylindrical lenses.

3. The display device according to claim 2, wherein:
the plurality of lenses have a rectangular cross section in a longitudinal direction and a semicircular cross section in a width direction; and
the plurality of lenses are configured to limit a viewing angle in the width direction.

4. The display device according to claim 1, wherein the plurality of lenses overlap the plurality of openings of the black matrix, respectively.

5. The display device according to claim 1, wherein the touch unit further includes:
a touch buffer layer disposed on the encapsulation layer;
a plurality of bridge metals disposed between the touch buffer layer and the black matrix;
a first touch insulating layer disposed between the plurality of bridge metals and the black matrix;
a second touch insulating layer disposed between the black matrix and the plurality of sensor metals;
a third touch insulating layer disposed between the plurality of sensor metals and the plurality of lenses; and
a touch protection layer disposed on the third touch insulating layer and the plurality of lenses.

6. The display device according to claim 5, wherein the plurality of sensor metals include:
a plurality of first sensor metals each including a plurality of first portions extending in a first direction between the plurality of sub-pixels and a plurality of second portions extending in a second direction different from the first direction between the plurality of sub-pixels, the plurality of second portions connecting the plurality of first portions to each other;
a plurality of second sensor metals alternately disposed with the plurality of first sensor metals in the second direction;
a plurality of third sensor metals disposed between the plurality of first sensor metals adjacent to each other in the first direction;
a plurality of fourth sensor metals disposed adjacent to the plurality of third sensor metals in the second direction; and
a plurality of fifth sensor metals disposed between the plurality of second sensor metals adjacent to each other in the first direction and adjacent to the plurality of fourth sensor metals in the second direction.

7. The display device according to claim 6, wherein:
each of the plurality of first sensor metals further includes a pair of protruding portions extending toward a corresponding second sensor metal, among the plurality of second sensor metals, from both ends of a first portion facing the corresponding second sensor metal, among the plurality of first portions; and
a first gap area and a second gap area are disposed between each of the pair of protruding portions and the corresponding second sensor metal.

8. The display device according to claim 7, wherein:
some of the plurality of lenses overlap the first gap area;
other lenses of the plurality of lenses are disposed to be spaced apart from the first gap area; and
the plurality of lenses are disposed to be spaced apart from the second gap area.

9. The display device according to claim 8, wherein the plurality of sensor variable regions include:
a first sensor variable region disposed on one side of one of the plurality of third sensor metals;
a second sensor variable region disposed on the other side of the one of the plurality of third sensor metals;
a third sensor variable region disposed on one side of one of the plurality of fourth sensor metals;
a fourth sensor variable region disposed on the other side of the one of the plurality of fourth sensor metals;
a fifth sensor variable region disposed on one side of one of the plurality of fifth sensor metals;
a sixth sensor variable region disposed on the other side of the one of the plurality of fifth sensor metals;
a seventh sensor variable region disposed between one of the plurality of third sensor metal and one of the plurality of fourth sensor metals;
an eighth sensor variable region disposed between one of the plurality of fourth sensor metal and one of the plurality of fifth sensor metals; and
a ninth sensor variable region overlapping the second gap area.

10. The display device according to claim 9, wherein:
each of the first sensor variable region and the second sensor variable region is disposed between one of the plurality of third sensor metals and one of the plurality of first sensor metals;
each of the third sensor variable region and the fourth sensor variable region is disposed between one of the plurality of fourth sensor metal and one of the plurality of first sensor metal; and
each of the fifth sensor variable region and the sixth sensor variable region is disposed between one of the plurality of fifth sensor metal and one of the plurality of second sensor metal.

11. The display device according to claim 6, wherein the plurality of bridge metals include:
a plurality of first bridge metals extending in the second direction in an area between the plurality of first sensor metals and the plurality of second sensor metals;
a plurality of second bridge metals overlapping the plurality of second sensor metals; and
a plurality of third bridge metals overlapping the plurality of first sensor metals.

12. The display device according to claim 11, further comprising:
a first bridge variable region disposed between some of the plurality of third bridge metals and the plurality of first bridge metals;
a second bridge variable region disposed between each of the plurality of first bridge metals; and
a third bridge variable region disposed between the plurality of first bridge metals and the plurality of second bridge metals,
wherein the plurality of first sensor metals and the plurality of first bridge metals are connected to each other respectively through a contact hole in the first bridge variable region.

13. The display device according to claim 1, wherein an additional sensor metal is disposed in a part or all the plurality of sensor variable regions.

14. The display device according to claim 9, wherein the ninth sensor variable region is disposed between the first sensor metal and the second sensor metal.

15. The display device according to claim 12, wherein an additional bridge metal is disposed in at least one of the first bridge variable region, the second bridge variable region and the third bridge variable region.

16. The display device according to claim 12, wherein the second bridge variable region is overlapped with the fourth sensor metal, and the third bridge variable region is overlapped with the second sensor metal.

17. A display device, comprising:
a substrate including a plurality of sub-pixels;
a light emitting element disposed in each of the plurality of sub-pixels;
a plurality of sensor metals disposed on the light emitting element;
a plurality of lenses disposed on the plurality of sensor metals and overlapped with the light emitting element; and
a plurality of sensor variable regions disposed between the plurality of sensor metals, and an additional sensor metal is disposed in a part or all the plurality of sensor variable regions,
wherein the plurality of sensor variable regions are not overlapped with the plurality of lenses.

18. The display device according to claim 17, wherein the plurality of sensor metals comprises:
a plurality of first sensor metals arranged in a matrix form; and
a plurality of second sensor metals alternately disposed with the plurality of first touch electrodes and arranged in a matrix form,
wherein the plurality of sensor variable regions are disposed between the plurality of first sensor metals and the plurality of second sensor metals.

19. The display device according to claim 18, further comprising:
a plurality of bridge metals connected the plurality of sensor metals to each other,
wherein the plurality of bridge metals comprises:
a plurality of first bridge metals disposed in an area between the plurality of first sensor metals and the plurality of second sensor metals;
a plurality of second bridge metals overlapping the plurality of second sensor metals; and
a plurality of third bridge metals overlapping the plurality of first sensor metals.

20. The display device according to claim 19, further comprising:
a first bridge variable region extending from the plurality of first bridge metals and overlapped with the plurality of first bridge metals;
a second bridge variable region disposed between each of the plurality of first bridge metals in the second direction; and
a third bridge variable region disposed between the plurality of first bridge metals and the plurality of second bridge metals, and
wherein an additional bridge metal is disposed in at least one of the first bridge variable region, the second bridge variable region and the third bridge variable region.
